(19) United States
(12) Patent Application Publication
(10) Pub. No.: US 2023/0173801 A1
(43) Pub. Date: Jun. 8, 2023

(54) STEREOSCOPIC IMAGE DISPLAY DEVICE AND METHOD OF MANUFACTURING THE SAME

(71) Applicant: SAMSUNG DISPLAY CO.,LTD., Yongin-si (KR)

(72) Inventors: YOUNG SANG HA, Yongin-si (KR); Jeong Woo Park, Yongin-si (KR)

(21) Appl. No.: 17/938,668

(22) Filed: Oct. 6, 2022

(30) Foreign Application Priority Data
Dec. 7, 2021 (KR) 10-2021-0173997

(51) Int. Cl. G02B 30/27; G02B 30/10

(52) U.S. Cl. CPC G02B 30/27; G02B 30/10

(57) ABSTRACT

A method of manufacturing a stereoscopic image display device includes forming a groove by etching an edge portion of a rear surface of a lens array substrate, depositing a sticky material layer in the groove, disposed a transparent adhesive layer that differs from the sticky material layer onto a top surface of a display panel, aligning the lens array substrate and the display panel by using a camera, and joining the display panel and the lens array substrate by using the transparent adhesive layer.

### CROSS-REFERENCE TO RELATED APPLICATION

The present application claims priority under 35 U.S.C. § 119(a) from Korean patent application 10-2021-0173997, filed on Dec. 7, 2021 in the Korean Intellectual Property Office, the contents of which are herein incorporated by reference in their entirety.

### TECHNICAL FIELD

The present disclosure generally relates to a display device, and more particularly, to a stereoscopic image display device for displaying a 3D image and a method of manufacturing the stereoscopic image display device.

### DISCUSSION OF THE RELATED ART

A stereoscopic image display device is a display device which allows a viewer recognize an image as a stereoscopic image by stimulating a visual sense of the viewer to perceived scenes in three dimensions. For example, a stereoscopic image display device provides different images to left and right eyes of the viewer, so that the viewer can view a stereoscopic image through binocular parallax between the left and right eyes.

A glass-free scheme in which a viewer does not wear any stereoscopic glasses includes a lenticular scheme in which a left eye image and a right eye image are separated from each other by using a cylindrical lens array, and a barrier scheme in which a left eye image and a right eye image are separated from each other by using a barrier, etc.

### SUMMARY

Embodiments provide a method of manufacturing a stereoscopic image display device, in which an easily separable sticky material layer is deposited in a groove at a rear surface of a lens array substrate, and alignment of a display panel and the lens array substrate is performed.

Embodiments also provide a stereoscopic image display device manufactured by the method.

In accordance with an embodiment of the present disclosure, there is provided a method of manufacturing a stereoscopic image display device. The method includes forming a groove by etching an edge portion of a rear surface of a lens array substrate, depositing a sticky material layer in the groove; disposing a transparent adhesive layer that differs from the sticky material layer onto a top surface of a display panel; aligning the lens array substrate and the display panel by using a camera; and joining the display panel and the lens array substrate by using the transparent adhesive layer.

The deposited sticky material layer may protrude from an unetched portion of the rear surface of the lens array substrate.

Aligning the lens array substrate and the display panel may include attaching the lens array substrate and the display panel to each other by using the sticky material layer; determining whether the lens array substrate and the display panel are misaligned by photographing a lens in the lens array substrate and a pixel in the display panel by using the camera; and physically separating the display panel and the lens array substrate from each other and reattaching the display panel and the lens array substrate to each other when the lens array substrate and the display panel are misaligned.

Aligning the display panel and the lens array substrate includes repeatedly attaching and separating the lens array substrate and display device until the lens array substrate and the display panel are aligned.

The lens array substrate may include lenticular lenses.

A thickness of the sticky material layer may be greater than a thickness of the transparent adhesive layer.

The sticky material layer may include a pressure sensitive adhesive.

The sticky material layer may include polydimethylsiloxane (PDMS).

An adhesive force of the transparent adhesive layer may be greater than an adhesive force of the sticky material layer.

The transparent adhesive layer may include an optically clear adhesive (OCA) film.

Both the transparent adhesive layer and the sticky material layer may be brought into contact with the display panel and the lens array substrate by the joining of the display panel and the lens array substrate.

The groove of the rear surface of the lens array substrate may overlap dead pixels of a pixel area of the display panel.

In accordance with another embodiment of the present disclosure, there is provided a stereoscopic image display device that includes a display panel that includes a pixel area that includes pixels; a lens array substrate disposed on the pixel area of the display panel, where the lens array substrate includes a lens array that forms a light field by refracting light output from the display panel; and a transparent adhesive layer and a sticky material layer that are disposed between the display panel and the lens array substrate and attach the display panel and the lens array substrate to each other. An edge of a rear surface of the lens array substrate includes a groove, and the sticky material layer fills the groove.

A thickness of the sticky material layer may be greater than a thickness of the transparent adhesive layer.

The sticky material layer may be in contact with a portion of a top surface of the display panel that faces the groove.

The transparent adhesive layer may be disposed on a portion of the display panel where the groove and the sticky material layer are not formed.

The lens array substrate may include lenticular lenses.

The sticky material layer may include a pressure sensitive adhesive.

The sticky material layer may include polydimethylsiloxane (PDMS).

The transparent adhesive layer may include an optically clear adhesive (OCA) film or an optically clear resin (OCR). An adhesive force of the transparent adhesive layer may be greater than an adhesive force of the sticky material layer.

In accordance with an embodiment of the present disclosure, there is provided a method of manufacturing a stereoscopic image display device. The method includes forming a groove by etching an edge portion of a rear surface of a lens array substrate, depositing a sticky material layer in the groove, aligning the lens array substrate and a display panel by using a camera, disposing a transparent adhesive layer that differs from the sticky material layer between the display panel and the lens array substrate, and joining the display panel and the lens array substrate by using the transparent adhesive layer.

The transparent adhesive layer may include an optically clear resin (OCR) that is a viscous liquid, and the OCR may be inserted into an empty space between the aligned display panel and the lens array substrate to fill the empty space.

Joining the display panel and the lens array substrate may include pressurizing the display panel and the lens array substrate in a vacuum state, where the OCR is heated and cured and joins the display panel and the lens array substrate.

### BRIEF DESCRIPTION OF THE DRAWINGS

FIG. 1 illustrates a lens array type stereoscopic image display device.

FIG. 2A is an exploded perspective view of a stereoscopic image display device in accordance with embodiments of the present disclosure.

FIG. 2B is a sectional view of a stereoscopic image display device in accordance with the embodiments of the present disclosure.

FIG. 3 is a plan view of a stereoscopic image display device shown in FIG. 2B.

FIG. 4 is a flowchart of a method of manufacturing a stereoscopic image display device in accordance with embodiments of the present disclosure.

FIGS. 5 to 8 are sectional views that illustrate of a method shown in FIG. 4.

FIG. 9 is a flowchart of a process of aligning a lens array substrate and a display panel that is included in the method shown in FIG. 4.

FIG. 10 illustrates a process of aligning a lens array substrate and a display panel shown in FIG. 9.

FIG. 11 is a flowchart of a method of manufacturing a stereoscopic image display device in accordance with embodiments of the present disclosure.

FIG. 12 is a plan view of an example of a stereoscopic image display device shown in FIG. 2B.

### DETAILED DESCRIPTION

Hereinafter, exemplary embodiments of the present disclosure will be described in more detail with reference to the accompanying drawings. Throughout the drawings, the same reference numerals may be given to the same elements, and overlapping descriptions thereof may be omitted.

In the drawing figures, it will be understood that when an element is referred to as being “between” two elements, it can be the only element between the two elements, or one or more intervening elements may also be present.

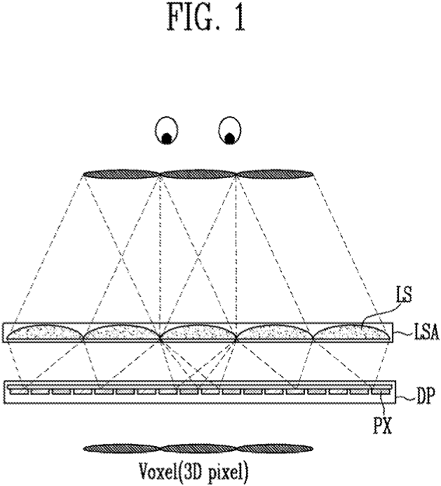

FIG. 1 illustrates a lens array type stereoscopic image display device.

Referring to FIG. 1, in an embodiment, a stereoscopic image display device includes a display panel DP and a lens array LSA.

The display panel DP includes pixels PX that display an image by emitting light. In an embodiment, each of the pixels PX outputs one of red light, green light, and blue light. However, the color of light emitted from the pixels PX is not limited thereto. In other embodiments, light is output of various other colors for full-color implementation.

The lens array LSA is disposed on the display panel DP, and includes lenses LS that refract light incident from the pixels PX. For example, the lens array LSA may be implemented as a lenticular lens array, or a micro lens array, etc.

A light field display is a 3D display that implements a stereoscopic image by forming a light field that is represented by a vector distribution of light that includes intensity and direction in space, using a flat panel display and an optical element, such as the lens array LSA. The light field display is a display technique in which a depth, a side, etc., of an object can be viewed, so that more natural stereoscopic image implementation is possible. Thus, various uses can be expected by fusing a light field display technique with an augmented reality (AR) technique, etc.

The light field can be implemented by various methods. For example, the light field can be formed by using a method of generating light fields in several directions by using several projectors, a method of controlling a direction of light by using a grating, a method of adjusting a direction and an intensity or luminance of light according to a combination of pixels by using two or more panels, a method of controlling a direction of light by using a pinhole or a barrier, or a method of controlling a refraction direction of light through a lens array, etc.

In an embodiment shown in FIG. 1, a lens array type stereoscopic image display device displays a stereoscopic 3D image by forming a light field.

A series of pixels PX are allocated to each lens LS, and light emitted from each pixel PX is refracted by the lens LS and then propagates in a specific direction, thereby forming a light field that can be expressed with an intensity and a direction of the light. When a viewer views a stereoscopic image display device within the light field formed as described above, the viewer experiences a stereoscopic effect of the corresponding image.

Image information according to a viewpoint of the viewer within the light field is defined and processed in units of voxels. The voxel is graphic information that defines a predetermined point in a three-dimensional space.

The resolution of a two-dimensional image is determined by the number, e.g., a density, of pixels with respect to the same area. For example, when the number of pixels with respect to the same area increases, the resolution increases. For example, the display panel DP that has a high pixel density can display a high-resolution image.

Similarly, when the number of voxels at the same viewpoint through the lens array LSA increases, the resolution of a stereoscopic image increases.

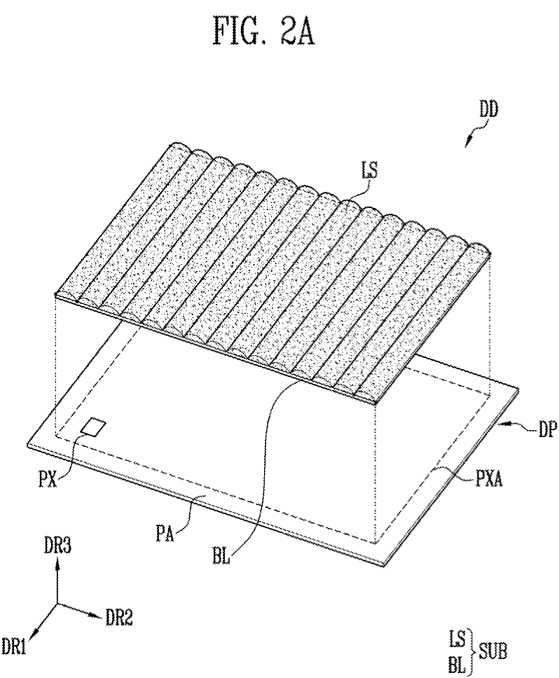

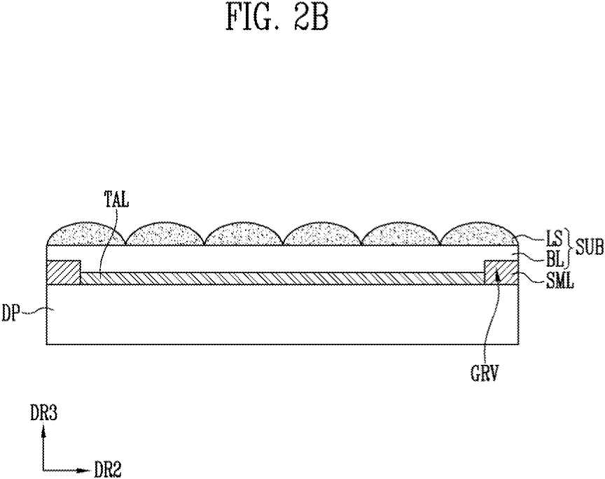

FIG. 2A is an exploded perspective view of a stereoscopic image display device in accordance with embodiments of the present disclosure. FIG. 2B is a sectional view of a stereoscopic image display device in accordance with the embodiments of the present disclosure.

Referring to FIGS. 2A and 2B, in an embodiment, the stereoscopic image display device DD may include a display panel DP and a lens array substrate SUB.

The display panel DP includes pixels PX, circuits and a driver that are used to drive the pixels PX. All or at least a portion of the display panel DP is flexible.

In an embodiment, the pixel PX include a self-luminous element. For example, the self-luminous element may be an organic light emitting element, an inorganic light emitting element, or a light emitting element configured with a combination of inorganic and organic materials.

However, embodiments are not necessarily limited thereto, and the display panel DP may be implemented as a liquid crystal display panel, a plasma display panel, or a quantum dot display panel, etc. When the display panel DP is a liquid crystal display panel, the display panel DP includes the liquid crystal display panel and a backlight unit.

The display panel DP includes a pixel area PXA and a peripheral area PA. For example, the pixel area PXA is parallel to a plane formed by a first direction DR1 and a second direction DR2 that intersects the first direction DR1.

The pixels PX are disposed in the pixel area PXA. For example, the pixel area PXA includes a light emitting element in each pixel PX and a pixel circuit connected to the light emitting element.

In an embodiment, the pixels PX disposed in the pixel area PXA are divided into activation pixels and dead pixels. The activation pixels actually emit light, thereby being involved in image display.

The dead pixels are manufactured together with the activation pixels for convenience of process, but are not used for actual image display. For example, pixels at an edge side of the pixel area PXA are not connected to signal lines or do not emit light due to a shape and a size of the display panel, a circuit design condition, or an image condition, etc. As described above, the pixels disposed at the edge side of the pixel area PXA that do not emit light are dead pixels.

The peripheral area PA is located at a least one side of the pixel area PXA. Drivers or driving circuits that drive the pixels PX and lines that connect between the pixels PX and the drivers are disposed in the peripheral area PA. The drivers perform various functions, such as that of a data driver, scan driver, a timing controller, etc.

For example, at least some of the drivers are disposed on a printed circuit board connected to the peripheral area PA. Alternatively, at least some of the drivers are integrated onto the peripheral area PA or mounted on the peripheral area PA.

The lens array substrate SUB is disposed on the pixel area PXA of the display panel DP. The lens array substrate SUB forms a light field by refracting light from the display panel DP. The lens array substrate SUB includes a base layer BL and a plurality of lenses LS formed on the top of the base layer BL.

The base layer BL includes a transparent film or glass.

For example, the base layer BL includes an organic material selected from at least one of polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (SAC), or cellulose acetate propionate (CAP).

Alternatively, in some embodiments, the base layer BL includes an inorganic material. For example, the base layer BL include at least one of silicon nitride, silicon oxide, silicon oxynitride, titanium oxide, or aluminum oxide, etc.

The lenses LS include the same material as the base layer BL.

The base layer BL and the lenses LS are integrally formed through an injection molding process. Alternatively, in an embodiment, the lens array substrate SUB is formed by allowing the lenses LS to adhere onto the base layer BL, using an adhesive.

In an embodiment, a lens array includes semi-cylindrical lenses LS, such as lenticular lenses, that extend in a first direction DR1. However, embodiments are not necessarily limited thereto, and other embodiments, the lenses LS are slanted and extend while being inclined obliquely with respect to the first direction DR1.

A size and an arrangement of the lenses LS can be determined by conditions, such as a size of the pixel area PXA, a viewing distance, a pixel size, a resolution, a pixel arrangement structure, etc.

However, embodiments are not necessarily limited thereto, and the lens LS may include a micro lens. When viewed on a plane, a micro lens has a shape such as a polygonal shape, a circular shape, or an elliptical shape.

A transparent adhesive layer TAL and a sticky material layer SML are disposed between the display panel DP and the lens array substrate SUB. The transparent adhesive layer TAL and the sticky material layer SML are used to join or bond the display panel DP and the lens array substrate SUB. Further, the sticky material layer SML is used in an alignment process before the lens array substrate SUB and the display panel DP are joined together.

In an embodiment, as shown in FIG. 2B, an edge of a rear surface of the base layer BL includes grooves GRV. A distance between a surface of the groove GRV and the display panel DP is greater than a distance between another portion of the rear surface of the base layer BL and the display panel DP. The grooves GRV overlap the dead pixels. The grooves GRV assist the alignment process that is performed before the lens array substrate SUB and the display panel DP are joined together.

In an alignment process between members, such as an ordinary substrate, an ordinary film, an ordinary panel, etc., an alignment key or alignment mark is inserted into a substrate, and the members to be joined are aligned with respect to the alignment key. However, forming an alignment key in the lens array substrate SUB is challenging due to manufacturing characteristics of the lens array substrate SUB that has a transparent film form. When an alignment key is inserted into the lens array substrate SUB, an effective area of the pixel area PXA, which is an area in which an image is displayed, decreases due to the insertion of the alignment key.

Instead of using an alignment key method, a software alignment method digitizes a misalignment between physically misaligned members, and displays an image by using an algorithm that compensates for the misalignment. However, a cost of developing and testing an algorithm in the software alignment method may increase, and product reliability and durability may decrease due to physical misalignments as a size of the display panel DP increases.

To address this situation, in an embodiment, a method is performed that physically aligns and joins the lens array substrate SUB and the display panel DP without inserting a alignment key.

In accordance with embodiments of the present disclosure, the stereoscopic image display device DD is provided, in which alignment and joining are accomplished by the grooves GRV at the edge of the rear surface of the base layer BL and the sticky material layer SML disposed in the grooves GRV.

The sticky material layer SML fills the groove GRV. In addition, the sticky material layer SML is in contact with a portion of a top surface of the display panel DP that faces the groove. A thickness of the sticky material layer SML is greater than a thickness of the transparent adhesive layer TAL.

In an embodiment, the sticky material layer SML includes a pressure sensitive adhesive. The pressure sensitive adhesive is an un unsolidified and semi-fluid material that can be adhere to an object to be attached by pressure. The pressure sensitive adhesive can be attached to an object by a low pressure, and no residue remains when the pressure sensitive adhesive is torn off. Accordingly, in a process of aligning the lens array substrate SUB and the display panel DP, the lens array substrate SUB and the display panel DP can be temporarily attached and fixed by the sticky material layer SML. In addition, the lens array substrate SUB and the display panel DP can be easily separated from or reattached to each other by the sticky material layer SML.

In an embodiment, the pressure sensitive adhesive includes one of a rubber-based adhesive, an acryl-based adhesive, or a silicon-based adhesive. For example, the pressure sensitive adhesive includes a material used for tape or a sticker label, etc. In an embodiment, the sticky material layer SML includes a silicon-based material such as polydimethylsiloxane (PDMS). PDMS is optically transparent and is chemically stable. In addition, PDMS is viscoelastic and thus can easily fill a space between the display panel DP and the lens array substrate SUB.

The transparent adhesive layer TAL is disposed on a portion of the display panel DP at which the sticky material layer SML is not disposed to join the display panel DP and the lens array substrate SUB. An adhesive force of the transparent adhesive layer TAL is greater than an adhesive force of the sticky material layer SML.

In an embodiment, the transparent adhesive layer TAL includes an optically clear adhesive (OCA) film. One surface, such as a rear surface, of the OCA film is attached onto the display panel DP, and the other surface, such as a top surface, of the OCA film is attached to the base layer BL of the lens array substrate SUB through a joining or bonding process. Since the OCA film is attached as a film to the display panel DP and the lens array substrate SUB, the usability of the OCA film is excellent, and the OCA film can be attached with a uniform thickness. The OCA film includes at least one of an acryl-based component, a silicon-based component, or a urethane-based component, etc.

When the transparent adhesive layer TAL and the sticky material layer SML include the same material, the transparent adhesive layer TAL and the sticky material layer SML have different compositions. Therefore, the adhesive force of the transparent adhesive layer TAL is greater than the adhesive force of the sticky material layer SML.

In an embodiment, the transparent adhesive layer TAL includes an optically clear resin (OCR). The OCR includes at least one of an acryl-based component, a silicon-based component, or a urethane-based component, etc. The OCR is provided between the display panel DP and the lens array substrate SUB in a liquid state and joins the display panel DP and the lens array substrate SUB while being cured. The OCR minimizes empty spaces such as gaps that may occur between the display panel DP and the lens array substrate SUB.

Although FIG. 2B illustrates an embodiment in which the transparent adhesive layer TAL and the sticky material layer SML are in contact with each other, embodiments of the present disclosure are not necessarily limited thereto, and other embodiments, the transparent adhesive layer TAL and the sticky material layer SML are spaced apart from each other.

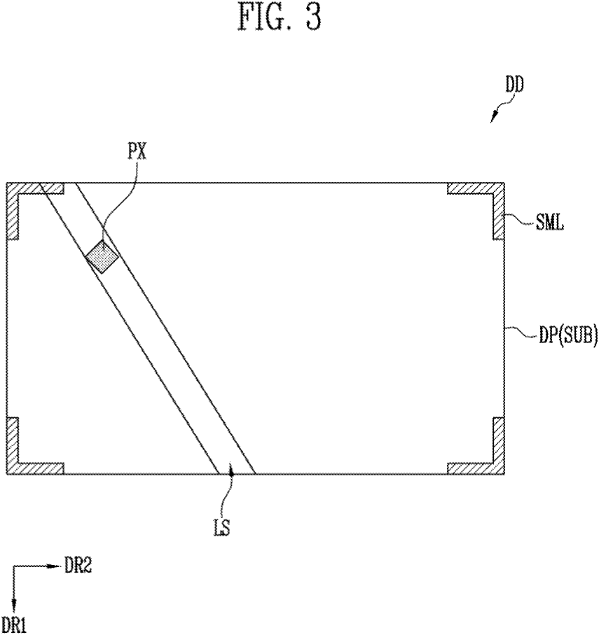

FIG. 3 is a plan view of a stereoscopic image display device shown in FIG. 2B.

Referring to FIGS. 2B and 3, in an embodiment, a stereoscopic image display device DD includes a display panel DP and a lens array substrate SUB.

FIG. 3 shows a state in which alignment of the display panel DP and the lens array substrate SUB is completed. For example, an alignment coordinate of a pixel PX and an alignment coordinate of a corresponding lens LS accord with each other. The stereoscopic image display device DD shown in FIG. 3 is a schematic planar view of which a sectional view is shown in FIG. 2B, and therefore, repeated descriptions of components described with reference to FIG. 2B may be omitted.

In an embodiment, as shown in FIG. 3, the lens LS is a lenticular lens, and extends obliquely with respect to the first direction DR1. However, embodiments are not necessarily limited thereto, and in other embodiments, the lens LS extends parallel to the first direction DR1, depending on an arrangement form of the pixel PX, a size of the pixel PX, a stereoscopic image driving method, etc.

The lens array substrate SUB include grooves GRV at four corner portions. In an embodiment, each groove GRV is bent at a corner portion of the lens array substrate SUB. However, embodiments are not necessarily limited thereto, and in other embodiments, the position, shape, and size of the groove GRV can vary. The groove GRV overlaps dead pixels of the display panel DP.

A sticky material layer SML fills the groove GRV between the display panel DP and the lens array substrate SUB.

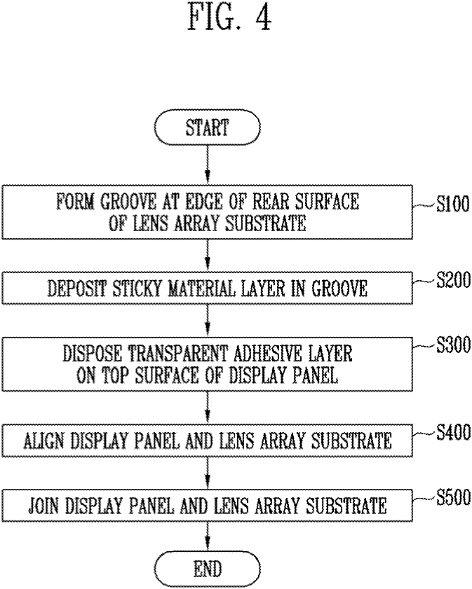

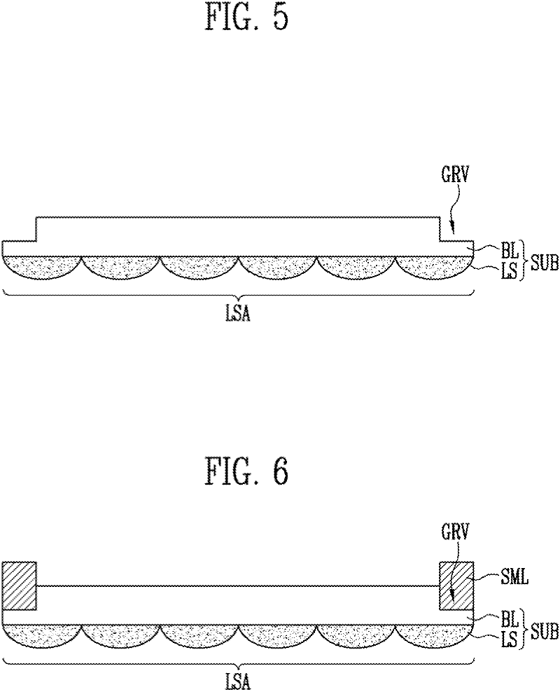

FIG. 4 is a flowchart of a method of manufacturing a stereoscopic image display device in accordance with embodiments of the present disclosure. FIGS. 5 to 8 are sectional views that illustrate a method shown in FIG. 4.

Referring to FIG. 2B to 8, in an embodiment, a method of manufacturing the stereoscopic image display device DD includes processes of forming a groove GRV at an edge of a rear surface of a lens array substrate SUB (S100), depositing a sticky material layer SML in the groove GRV (S200), disposing a transparent adhesive layer TAL onto a top surface of a display panel DP (S300), aligning the display panel DP and the lens array substrate SUB (S400), and joining or bonding the display panel DP and the lens array substrate SUB (S500).

As shown in FIG. 5, in an embodiment, a groove GRV is formed by etching an edge portion of a rear surface of a lens array substrate SUB (S100). FIG. 5 shows an example in which the lens array substrate SUB is turned upside down.

The lens array substrate SUB includes a base layer BL and a plurality of lenses LS formed on the top of the base layer BL. The arrangement of the lenses LS forms a lens array LSA.

In an embodiment, as shown in FIG. 3, the groove GRV is formed at each corner portion of the lens array substrate SUB. Although FIGS. 3 and 5 illustrate a case where grooves GRV are formed at edges of the lens array substrate SUB, embodiments of the present disclosure are not necessarily limited thereto. For example, in other embodiments, the grooves GRV are formed at inner portions of the lens array substrate SUB in which side surfaces of the lens array substrate SUB are not etched.

The grooves GRV are formed through an exposure process that uses a photoresist, a chemical wet etching process or a physical dry etching process, etc.

As shown in FIG. 6, in an embodiment, a sticky material layer SML is deposited in the groove GRV in the rear surface of the lens array substrate SUB (S200).

The sticky material layer SML attaches and fixes to a surface of the groove GRV. In an embodiment, the sticky material layer SML includes a pressure sensitive adhesive. Alternatively, in an embodiment, the sticky material layer SML includes a sticky polydimethylsiloxane (PDMS) material.

The deposited sticky material layer SML protrudes from an unetched portion of the rear surface of the lens array substrate SUB. Since the sticky material layer SML is viscoelastic, the shape of the sticky material layer SML that protrudes from a rear surface of the base layer BL can be maintained. The sticky material layer SML can be formed in the groove GRV through various processes, such as a deposition process, a coating process, or an inkjet process, etc., which are known in the art.

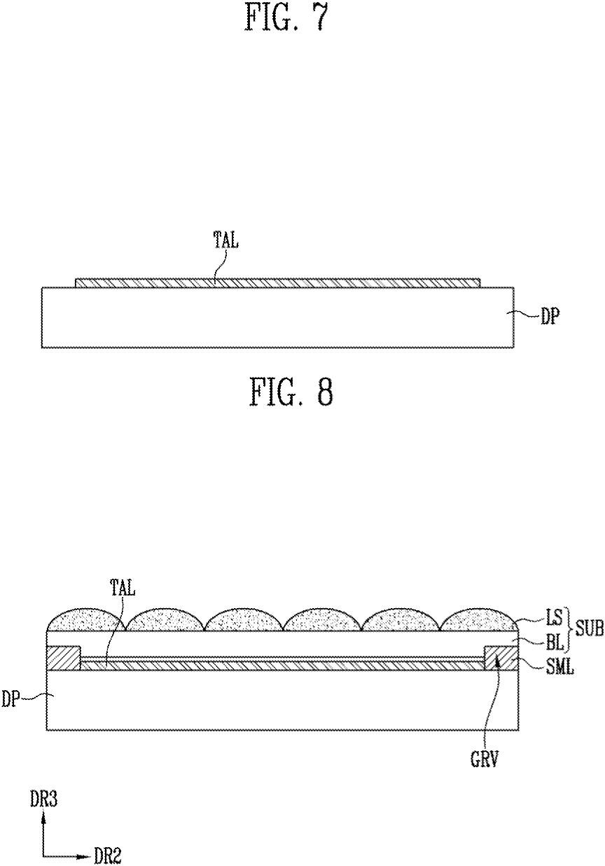

As shown in FIG. 7, in an embodiment, a transparent adhesive layer TAL that differs from the sticky material layer SML is disposed on a top surface of a display panel DP (S300). The transparent adhesive layer TAL is disposed on the display panel DP while avoiding the groove GRV and the sticky material layer SML. For example, the transparent adhesive layer TAL is disposed on a portion of the display panel DP where the groove GRV and the sticky material layer SML are not formed.

In an embodiment, the transparent adhesive layer TAL includes an optically clear adhesive (OCA) film. For example, the transparent adhesive layer TAL is attached as a film onto the display panel DP.

An adhesive force of the transparent adhesive layer TAL is greater than an adhesive force of the sticky material layer SML. Accordingly, the film-like transparent adhesive layer TAL does not come in contact with the lens array substrate SUB in an alignment process in which the display panel DP and the lens array substrate SUB are attached and separated. A thickness of the transparent adhesive layer TAL is less than a thickness of the sticky material layer SML. For example, the thickness of the transparent adhesive layer TAL is less than a thickness of a portion of the sticky material layer SML that protrudes from the rear surface of the base layer BL, before a joining process (see FIG. 8).

As shown in FIG. 8, in an embodiment, the lens array substrate SUB and the display panel DP are aligned (S400). For example, the lens array substrate SUB on which the sticky material layer SML is attached is disposed on the display panel DP for alignment. A very weak pressure is applied to the lens array substrate SUB, so that the lens array substrate SUB and the display panel DP are attached to each other by the sticky material layer SML. Since the thickness of the transparent adhesive layer TAL is less than the thickness of a protruding portion of the sticky material layer SML, a gap can occur between the transparent adhesive layer TAL and the base layer BL. Thus, the lens array substrate SUB and the display panel DP can be easily separated from each other.

A pixel PX of the display panel DP and a lens LS of the lens array substrate SUB that are attached to each other can be photographed with a camera. A position, such as a two-dimensional coordinate and an angle inclination with respect to a reference, of the pixel PX and a position, such as a two-dimensional coordinate and an angle inclination with respect to a reference, of the lens LS corresponding thereto are compared based on data obtained by photographing the pixel PX and the lens LS. Whether the display panel DP and the lens array substrate SUB are misaligned can be determined based on a comparison result.

When the display panel DP and the lens array substrate SUB are misaligned, the display panel DP and the lens array substrate SUB are separated and reattached to each other, based on calculated data. Since the adhesive force between the display panel DP and the lens array substrate SUB is weak, the display panel DP and the lens array substrate SUB can be easily separated from each other through a simple operation such as lifting the lens array substrate SUB.

The alignment of the display panel DP and the lens array substrate SUB is completed by repeating the separation and reattachment processes as described above.

The display panel DP and the lens array substrate SUB are joined together by using the transparent adhesive layer TAL (S500). In an embodiment, a top surface of the transparent adhesive layer TAL is attached to the base layer BL by pressurizing the display panel DP and the lens array substrate SUB in a vacuum state. The viscoelastic sticky material layer SML is compressed or flows therearound. Accordingly, as shown in FIG. 2B, the display panel DP and the lens array substrate SUB are joined together without any empty space therebetween. For example, a portion of the sticky material layer SML fills a space between the sticky material layer SML and the transparent adhesive layer TAL. Both the transparent adhesive layer and the sticky material layer are brought into contact with the display panel and the lens array substrate by the joining of the display panel and the lens array su bstrate.

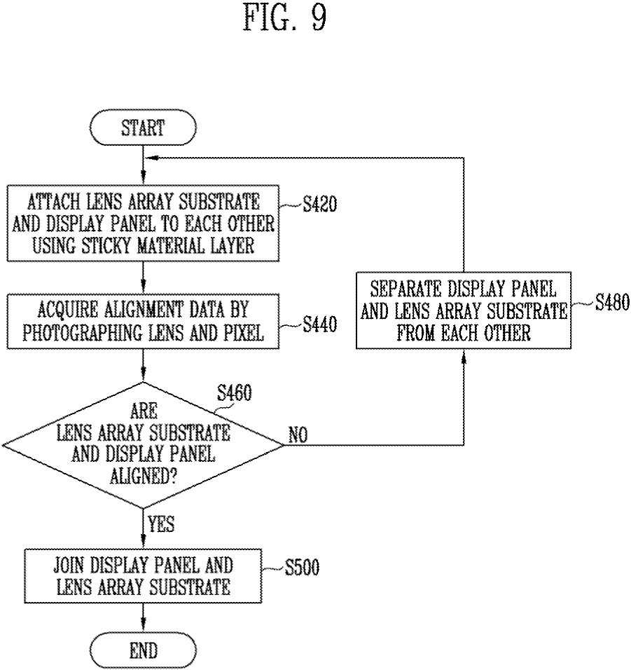

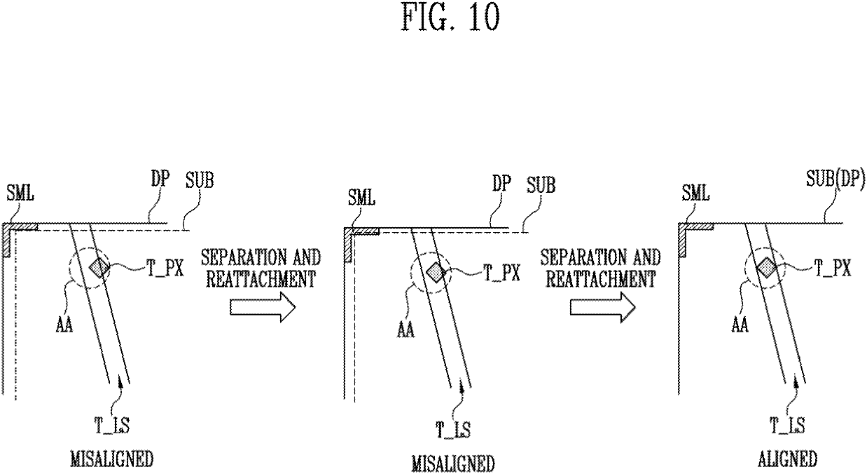

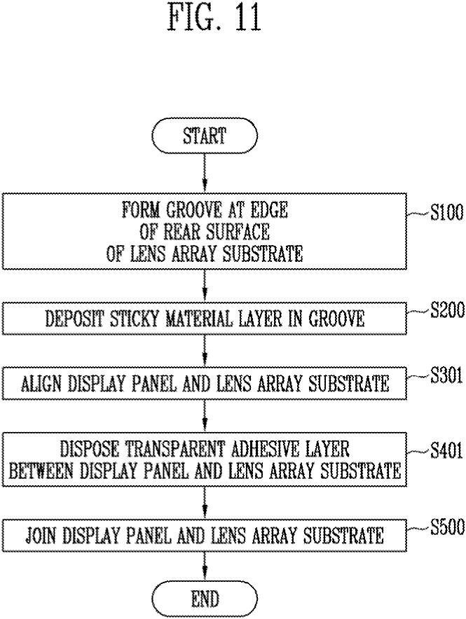

FIG. 9 is a flowchart of a process of aligning the lens array substrate and the display panel that is included in a method shown in FIG. 4. FIG. 10 illustrates an example of a process of aligning the lens array substrate and the display panel shown in FIG. 9.

Referring to FIGS. 4, 8, 9, and 10, in an embodiment, the process of aligning the lens array substrate SUB and the display panel DP (S400) includes processes of attaching the lens array substrate SUB and the display panel DP to each other using the sticky material layer SML (S420), acquiring alignment data by photographing a target lens T_LS and a target pixel T_PX (S440), and determining whether the lens array substrate SUB and the display panel DP are misaligned, based on the alignment data (S460).

As described with reference to FIG. 8, in an embodiment, the lens array substrate SUB and the display panel DP are attached to each other by the sticky material layer SML for alignment (S420).

The lens array substrate SUB and the display panel DP, which are attached, are photographed by a camera, and alignment data is acquired through data obtained by photographing the lens array substrate SUB and the display panel DP. For example, the alignment data includes position information of a target lens T_LS and a target pixel T_PX. The position information of each of the target lens T_LS and the target pixel T_PX includes information on a two-dimensional coordinate, such as, an x-y coordinate and an angle inclination with respect to a reference.

For example, as shown in FIG. 10, the target pixel T_PX and the target lens T_LS should be located at an exact angle in a predetermined alignment area AA. Whether the display panel DP and the lens array substrate SUB are misaligned can be determined based on the alignment data. Although FIG. 10 illustrates alignment of a single pixel and a single lens, embodiments are not necessarily limited thereto, and whether the display panel DP and the lens array substrate SUB are misaligned can be determined based on positions of at least one pixel and at least one lens.

When the alignment of the display panel DP and the lens array substrate SUB is satisfactory, the display panel DP and the lens array substrate SUB are joined together (S500).

When the lens array substrate SUB and the display panel DP are misaligned, the display panel DP and the lens array substrate SUB are physically separated from each other (S480). Since the adhesive force between the display panel DP and the lens array substrate SUB is relatively weak, the display panel DP and the lens array substrate SUB can be easily separated from each other. In addition, the sticky material layer SML remains sticky.

In addition, the alignment of the lens array substrate SUB and the display panel DP is adjusted based on the alignment data, and the lens array substrate SUB and the display panel DP are reattached to each other (S420). This process can be repeated until it is determined that the alignment of the display panel DP and the lens array substrate SUB is satisfactory. Accordingly, the accuracy of the process of aligning the display panel DP and the lens array substrate SUB can be increased.

As described above, in a method of manufacturing the stereoscopic image display device in accordance with embodiments of the present disclosure, a process of aligning the display panel and the lens array substrate, which can be attached to and separated from each other many times, is performed by using a sticky material layer that includes a pressure sensitive adhesive, etc., without insertion of any alignment key. Further, the locations of the groove and the sticky material layer of the lens array substrate correspond to dead pixels of the display panel. Thus, an accuracy of a process of aligning the display panel and the lens array substrate is considerably increased without damaging the display panel and the lens array substrate through physical alignment correction based on the repeated attachment and separation of the display panel and the lens array substrate, and a decrease in effective display area and image distortion due to additional material, such as the alignment key, etc., for alignment is minimized or prevented.

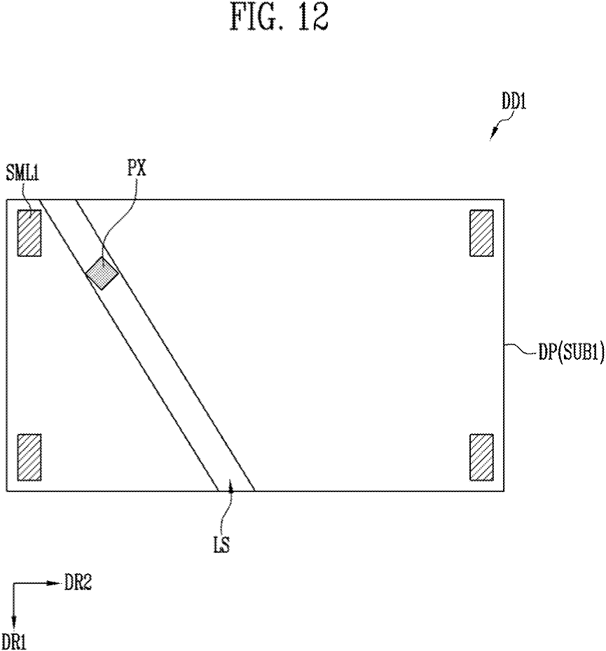

FIG. 11 is a flowchart of a method of manufacturing a stereoscopic image display device, according to an embodiment of the disclosure.

In FIG. 11, processes identical to those described with reference to FIG. 4 may be designated by like reference numerals, and repeated descriptions thereof may be omitted.

Referring to FIG. 11, in an embodiment, a method of manufacturing a stereoscopic image display device includes processes of forming a groove at an edge of a rear surface of a lens array substrate (S100), depositing a sticky material layer in a groove (S200), aligning a display panel and the lens array substrate (S301), disposing a transparent adhesive layer between the display panel and the lens array substrate (S401), and joining the display panel and the lens array substrate (S500).

In an embodiment, the display panel and the lens array substrate are aligned before the transparent adhesive layer is disposed (S301). The process of aligning the display panel and the lens array substrate is performed as described with reference to FIGS. 9 and 10.

When the alignment of the display panel and the lens array substrate is completed, a transparent adhesive layer is disposed between the display panel and the lens array substrate (S401). In an embodiment, the transparent adhesive layer includes an optically clear resin (OCR). For example, the OCR is a viscous liquid and is inserted to fill an empty space between the aligned display panel and the lens array substrate.

Subsequently, the display panel and the lens array substrate are joined together (S500). For example, the display panel and the lens array substrate are pressurized in a vacuum state, and the OCR is heated and cured, thereby joining the display panel and the lens array substrate (S500).

FIG. 12 is a plan view of a stereoscopic image display device shown in FIG. 2B.

In FIG. 12, components identical to those described with reference to FIGS. 2B and 3 may be designated by like reference numerals, and repeated descriptions thereof may be omitted.

Referring to FIG. 12, in an embodiment, a stereoscopic image display device DD1 includes a display panel DP and a lens array substrate SUB1.

The lens array substrate SUB1 includes grooves at four corner portions. In an embodiment, each groove is spaced apart from the corner portion of the lens array substrate SUB at a predetermined distance. In addition, the groove has a rectangular planar shape.

A sticky material layer SML1 is formed that fills the groove between the display panel DP and the lens array substrate SUB1. Therefore, the sticky material layer SML1 also corresponds to the planar shape of the groove. The sticky material layer SML1 overlaps the dead pixels of the display panel DP.

As described above, in a stereoscopic image display device and a method of manufacturing the same in accordance with embodiments of the present disclosure, the accuracy of the process of aligning the display panel and the lens array substrate is increased without damaging the display panel and the lens array substrate through physical alignment correction processes based on repeated attaching and separating of the display panel and the lens array substrate, and a decrease in effective display area and an image distortion due to an additional material, such as an alignment key, etc., for alignment is minimized or prevented.

Embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of embodiments of the present disclosure as set forth in the following claims.

What is claimed is:

1. A method of manufacturing a stereoscopic image display device, the method comprising:
forming a groove by etching an edge portion of a rear surface of a lens array substrate;
depositing a sticky material layer in the groove;
disposing a transparent adhesive layer that differs from the sticky material layer onto a top surface of a display panel;
aligning the lens array substrate and the display panel by using a camera; and
joining the display panel and the lens array substrate by using the transparent adhesive layer.

2. The method of claim 1, wherein the deposited sticky material layer protrudes from an unetched portion of the rear surface of the lens array substrate.

3. The method of claim 2, wherein aligning the lens array substrate and the display panel comprises:
attaching the lens array substrate and the display panel to each other by using the sticky material layer;
determining whether the lens array substrate and the display panel are misaligned by photographing a lens in the lens array substrate and a pixel in the display panel by using the camera; and
physically separating the display panel and the lens array substrate from each other and reattaching the display panel and the lens array substrate to each other when the lens array substrate and the display panel are misaligned.

4. The method of claim 3, wherein aligning the display panel and the lens array substrate includes repeatedly attaching and separating the lens array substrate and display device until the lens array substrate and the display panel are aligned.

5. The method of claim 2, wherein the lens array substrate includes lenticular lenses.

6. The method of claim 2, wherein a thickness of the sticky material layer is greater than a thickness of the transparent adhesive layer.

7. The method of claim 2, wherein the sticky material layer includes a pressure sensitive adhesive.

8. The method of claim 2, wherein the sticky material layer includes polydimethylsiloxane (PDMS).

9. The method of claim 7, wherein an adhesive force of the transparent adhesive layer is greater than an adhesive force of the sticky material layer.

10. The method of claim 1, wherein the transparent adhesive layer includes an optically clear adhesive (OCA) film.

11. The method of claim 1, wherein both the transparent adhesive layer and the sticky material layer are brought into contact with the display panel and the lens array substrate by the joining of the display panel and the lens array substrate.

12. The method of claim 1, wherein the groove of the rear surface of the lens array substrate overlaps dead pixels of a pixel area of the display panel.

13. A stereoscopic image display device, comprising:
a display panel that includes a pixel area that includes pixels;
a lens array substrate disposed on the pixel area of the display panel, wherein the lens array substrate includes a lens array that forms a light field by refracting light output from the display panel; and
a transparent adhesive layer and a sticky material layer that are disposed between the display panel and the lens array substrate and attach the display panel and the lens array substrate to each other,
wherein an edge of a rear surface of the lens array substrate includes a groove, and
wherein the sticky material layer fills the groove.

14. The stereoscopic image display device of claim 13, wherein a thickness of the sticky material layer is greater than a thickness of the transparent adhesive layer.

15. The stereoscopic image display device of claim 14, wherein the sticky material layer is in contact with a portion of a top surface of the display panel that faces the groove.

16. The stereoscopic image display device of claim 14, wherein the transparent adhesive layer is disposed on a portion of the display panel where the groove and the sticky material layer are not formed.

17. The stereoscopic image display device of claim 14, wherein the lens array substrate includes lenticular lenses.

18. The stereoscopic image display device of claim 14, wherein the sticky material layer includes a pressure sensitive adhesive.

19. The stereoscopic image display device of claim 14, wherein the sticky material layer includes polydimethylsiloxane (PDMS).

20. The stereoscopic image display device of claim 14, wherein the transparent adhesive layer includes an optically clear adhesive (OCA) film or an optically clear resin (OCR), and
wherein an adhesive force of the transparent adhesive layer is greater than an adhesive force of the sticky material layer.

21. A method of manufacturing a stereoscopic image display device, the method comprising:
forming a groove by etching an edge portion of a rear surface of a lens array substrate;
depositing a sticky material layer in the groove;
aligning the lens array substrate and a display panel by using a camera;
disposing a transparent adhesive layer that differs from the sticky material layer between the display panel and the lens array substrate; and
joining the display panel and the lens array substrate by using the transparent adhesive layer.

22. The method of claim 21, wherein, the transparent adhesive layer includes an optically clear resin (OCR) that is a viscous liquid, and the OCR is inserted into an empty space between the aligned display panel and the lens array substrate and fills the empty space.

23. The method of claim 21, wherein joining the display panel and the lens array substrate includes pressurizing the display panel and the lens array substrate in a vacuum state, wherein the OCR is heated and cured and joins the display panel and the lens array substrate.
